(19) United States
(12) Patent Application Publication
(10) Pub. No.: US 2025/0204076 A1
(43) Pub. Date: Jun. 19, 2025

(54) ELECTRONIC CIRCUIT MODULE

(71) Applicant: Murata Manufacturing Co., Ltd., Kyoto (JP)

(72) Inventors: Takuo WAKAOKA, Kyoto (JP); Yoshifumi TAKAHASHI, Kyoto (JP); Riki SHIMABUKURO, Kyoto (JP); Kentaro TANABE, Kyoto (JP); Yasuhiro MURASE, Kyoto (JP)

(21) Appl. No.: 19/066,883

(22) Filed: Feb. 28, 2025

Related U.S. Application Data
(63) Continuation of application No. PCT/JP2023/020419, filed on Jun. 1, 2023.

(30) Foreign Application Priority Data
Sep. 2, 2022 (JP) 2022-139683

(51) Int. Cl. H10F 39/90; H01L 25/16

(52) U.S. Cl. CPC H10F 39/90; H01L 25/167

(57) ABSTRACT

An electronic circuit module is an electronic circuit module mounted on a motherboard having a power supply source. The electronic circuit module includes a photoelectric conversion unit which performs conversion between an optical signal and an electric signal, a processor unit which performs computational processing by using an electric signal, a power conversion unit which converts power from the power supply source and which supplies power to the photoelectric conversion unit and the processor unit, and a package substrate on which the photoelectric conversion unit, the processor unit, and the power conversion unit are mounted. The photoelectric conversion unit, the processor unit, and the power conversion unit are connected only through a conductor pattern formed on/in the package substrate.

### CROSS REFERENCE TO RELATED APPLICATION

This is a continuation of International Application No. PCT/JP2023/020419 filed on Jun. 1, 2023 which claims priority from Japanese Patent Application No. 2022-139683 filed on Sep. 2, 2022. The contents of these applications are incorporated herein by reference in their entireties.

### BACKGROUND ART

### Technical Field

The present disclosure relates to an electronic circuit module including a photoelectric conversion unit, which performs conversion between optical signals and electric signals, a processor unit, and a power conversion unit.

Patent Document 1 describes a circuit unit including a photonic package element, a processor element, an electronic device, an electronic circuit element, and an interposer. The photonic package element is connected to the processor element through electronic devices and electronic circuit elements in the interposer.

Patent Document 1: U.S. Patent Application Publication No. 2021/0091056

### BRIEF SUMMARY

However, a device of the related art, as described in Patent Document 1, may have insufficient information transmission efficiency or insufficient power-supply efficiency.

The present disclosure provides an electronic circuit module which achieves high information transmission efficiency and high power-supply efficiency.

An electronic circuit module according to an embodiment of the disclosure is an electronic circuit module mounted on a motherboard having a power supply source. The electronic circuit module includes a photoelectric conversion unit that performs conversion between an optical signal and an electric signal, a processor unit that performs computational processing by using the electric signal, a power conversion unit that converts power from the power supply source and that supplies power to the photoelectric conversion unit and the processor unit, and a package substrate that has the photoelectric conversion unit, the processor unit, and the power conversion unit which are mounted thereon. The photoelectric conversion unit, the processor unit, and the power conversion unit are connected only through a conductor pattern formed on/in the package substrate.

In this configuration, the photoelectric conversion unit and the processor unit are connected only through the conductor pattern formed on/in the package substrate, not through the motherboard. This improves the information transmission efficiency. The photoelectric conversion unit, the processor unit, and the power conversion unit are connected only through the conductor pattern formed on/in the package substrate, not through the motherboard. This improves the efficiency of power supply from the power conversion unit to the photoelectric conversion unit and the processor unit.

This disclosure achieves high information transmission efficiency and high power-supply efficiency.

### BRIEF DESCRIPTION OF DRAWINGS

FIG. 1 is a functional block diagram illustrating an exemplary circuit configuration of an electronic circuit module according to a first embodiment.

FIG. 2 is a side view of the configuration of an electronic circuit module according to the first embodiment.

FIG. 3 is a side view of the state in which an electronic circuit module according to the first embodiment is mounted on a motherboard.

FIG. 4 is a side view of the configuration of an electronic circuit module according to a second embodiment.

FIG. 5 is a side view of the configuration of an electronic circuit module according to a third embodiment.

FIG. 6A is a plan view of the configuration of an electronic circuit module according to a fourth embodiment;

FIG. 6B is a side view along A-A′ in FIG. 6A; FIG. 6C is a sectional view along B-B′ in FIG. 6A.

FIG. 7A is a diagram illustrating an exemplary wiring pattern of a data communication system in an electronic circuit module according to the fourth embodiment; FIG. 7B is a diagram illustrating an exemplary wiring pattern of a power supply system in an electronic circuit module according to the fourth embodiment.

FIG. 8A is a plan view of the configuration of an electronic circuit module according to a fifth embodiment;

FIG. 8B is a diagram illustrating an exemplary wiring pattern of a data communication system in an electronic circuit module according to the fifth embodiment; FIG. 8C is a diagram illustrating an exemplary wiring pattern of a power supply system in an electronic circuit module according to the fifth embodiment.

FIG. 9A is a plan view of the configuration of an electronic circuit module according to a sixth embodiment;

FIG. 9B is a diagram illustrating an exemplary wiring pattern of a data communication system in an electronic circuit module according to the sixth embodiment; FIG. 9C is a diagram illustrating an exemplary wiring pattern of a power supply system in an electronic circuit module according to the sixth embodiment.

FIG. 10A is a plan view of the configuration of an electronic circuit module according to a seventh embodiment;

FIG. 10B is a diagram illustrating an exemplary wiring pattern of a data communication system in an electronic circuit module according to the seventh embodiment; FIG. 10C is a diagram illustrating an exemplary wiring pattern of a power supply system in an electronic circuit module according to the seventh embodiment.

FIGS. 11A and 11B are plan views of the configuration of an electronic circuit module according to an eighth embodiment.

FIG. 12A is a diagram illustrating an exemplary wiring pattern of a data communication system in an electronic circuit module according to the eighth embodiment; FIG. 12B is a diagram illustrating an exemplary wiring pattern of a power supply system in an electronic circuit module according to the eighth embodiment.

FIG. 13A is a plan view of the configuration of an electronic circuit module according to a ninth embodiment;

FIGS. 13B and 13C are diagrams illustrating different examples of a cross section along C-C′ in FIG. 13A.

FIG. 14A is a diagram illustrating an exemplary wiring pattern of a data communication system in an electronic circuit module according to the ninth embodiment;

FIG. 14B is a diagram illustrating an exemplary wiring pattern of a power supply system in an electronic circuit module according to the ninth embodiment.

### DESCRIPTION OF EMBODIMENTS

### First Embodiment

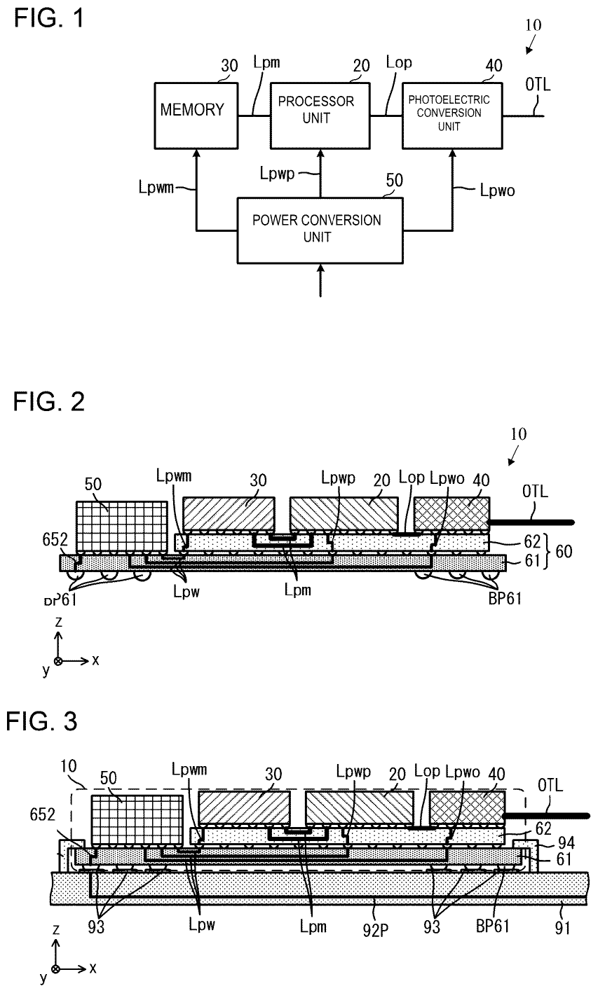

An electronic circuit module according to a first embodiment of the present disclosure will be described by referring to drawings. FIG. 1 is a functional block diagram illustrating an exemplary circuit configuration of an electronic circuit module according to the first embodiment. FIG. 2 is a side view of the configuration of an electronic circuit module according to the first embodiment. FIG. 3 is a side view of the state in which an electronic circuit module according to the first embodiment is mounted on a motherboard. In FIGS. 2 and 3, wiring patterns formed on/in substrates are also illustrated by using solid lines.

### (The Circuit Configuration of an Electronic Circuit Module 10)

As illustrated in FIG. 1, an electronic circuit module 10 includes a processor unit 20, a memory 30, a photoelectric conversion unit 40, and a power conversion unit 50.

The processor unit 20 is connected to the memory 30 through an information processing bus Lpm. The processor unit 20 is connected to the photoelectric conversion unit 40 through a data transmission line Lop. The photoelectric conversion unit 40 is connected to the outside through an optical waveguide OTL.

The processor unit 20 performs predetermined computational processing in accordance with an electric signal which is input from the photoelectric conversion unit 40 through the data transmission line Lop. At that time, the processor unit 20 performs computational processing by using the memory 30 connected through the information processing bus Lpm.

The processor unit 20 outputs a computation result as an electric signal which is input to the photoelectric conversion unit 40 through the data transmission line Lop.

The photoelectric conversion unit 40 converts an optical signal, which is received through the optical waveguide OTL, to an electric signal, and outputs the conversion result to the processor unit 20 through the data transmission line Lop. The photoelectric conversion unit 40 converts an electric signal, which is received from the processor unit 20 through the data transmission line Lop, to an optical signal, and outputs the conversion result to the outside through the optical waveguide OTL.

The power conversion unit 50 is connected to the processor unit 20 through a power supply line-for-processor Lpwp; to the memory 30 through a power supply line-for-memory Lpwm; and to the photoelectric conversion unit 40 through a power supply line-for-photoelectric-conversion-unit Lpwo.

The power conversion unit 50 converts input power from a power supply of an outside component (a motherboard described below) to power for the processor unit 20, power for the memory 30, and power for the photoelectric conversion unit 40, and supplies the conversion results to the processor unit 20, the memory 30, and the photoelectric conversion unit 40.

Thus, use of optical signals enables the information transmission rate to be made higher than that in the case in which all signals are electric signals.

### (The Configuration of the Electronic Circuit Module 10)

As illustrated in FIG. 2, the electronic circuit module 10 includes the processor unit 20, the memory 30, the photoelectric conversion unit 40, the power conversion unit 50, and a package substrate 60.

Each of the processor unit 20, the memory 30, the photoelectric conversion unit 40, and the power conversion unit 50 is a mount electronic component which includes a housing, which has a predetermined shape, and multiple terminal conductors. In the housing, a functional unit for implementing the corresponding unit or the like is formed. The terminal conductors are arranged in a predetermined pattern on the undersurface of the housing.

The package substrate 60 includes a first substrate 61 and a second substrate 62. The first substrate 61 and the second substrate 62 are flat plates. For example, the planar area (the area viewed in the z-axis direction in FIGS. 2 and 3) of the second substrate 62 is smaller than the planar area of the first substrate 61. The planar area of the first substrate 61 and that of the second substrate 62 are each smaller than the planar area of a motherboard 91 on which the electronic circuit module 10 is mounted.

The processor unit 20, the memory 30, and the photoelectric conversion unit 40 are mounted on a surface of the second substrate 62.

The data transmission line Lop, which connects the processor unit 20 to the photoelectric conversion unit 40, is formed only by conductor patterns formed on the second substrate 62. In other words, the data transmission line Lop does not go through the motherboard 91 on which the electronic circuit module 10 is mounted. Thus, the data transmission line Lop may be made short, achieving a reduction of the transmission loss and delay of the data transmission line Lop.

Similarly, like the data transmission line Lop, the information processing bus Lpm, which connects the processor unit 20 to the memory 30, is formed only by conductor patterns formed in the second substrate 62. In other words, the information processing bus Lpm does not go through the motherboard 91 on which the electronic circuit module 10 is mounted. Thus, the information processing bus Lpm may be made short, achieving a reduction of the transmission loss and delay of the information processing bus Lpm.

The processor unit 20 and the photoelectric conversion unit 40 can be disposed close to each other. The distance between the processor unit 20 and the photoelectric conversion unit 40 can be made shortest as much as possible. For example, the processor unit 20 and the photoelectric conversion unit 40 can be disposed close as much as possible in view of the pattern formation accuracy of the second substrate 62 and the mount accuracy of the processor unit 20 and the photoelectric conversion unit 40. For example, the distance can be equal to or less than the length of the long side of the processor unit 20 or the photoelectric conversion unit 40, and can be equal to or less than a half of the long side or the length of the short side. When the processor unit 20 or the photoelectric conversion unit 40 forms a square in plan view, the distance is to be equal to or less than a side, and can be equal to or less than a half of a side.

Thus, such a short physical distance between the processor unit 20 and the photoelectric conversion unit 40 easily causes the data transmission line Lop to be made short.

Further, the conductor patterns forming the data transmission line Lop can be formed on the surface of the second substrate 62. Thus, the data transmission line Lop does not have a portion extending in the thickness direction of the second substrate 62, achieving a reduction of the transmission loss and delay.

The data transmission line Lop may connect the processor unit 20 to the photoelectric conversion unit 40 at the shortest distance in plan view. Specifically, for example, each of the conductor patterns forming the data transmission line Lop may be a conductor pattern which connects a terminal of the processor unit 20 to a terminal of the photoelectric conversion unit 40 straight in plan view. This achieves a further reduction of the transmission loss and delay of the data transmission line Lop.

Like the relationship between the processor unit 20 and the photoelectric conversion unit 40, the processor unit 20 and the memory 30 can be disposed close to each other. Like the data transmission line Lop, the information processing bus Lpm can be short. This achieves suppression of the transmission loss and transmission delay between the processor unit 20 and the memory 30.

The second substrate 62 can have a high wiring density of conductor patterns. Thus, the number of conductor patterns per unit area may be increased. This increases a range of choices of wiring patterns of the data transmission line Lop between the processor unit 20 and the photoelectric conversion unit 40 and that of the information processing bus Lpm which connects the processor unit 20 to the memory 30, and achieves easy formation of short conductor patterns connecting these.

The second substrate 62 is formed of a material (for example, a material whose main material is Si or a resin such as a dielectric having a low dielectric dissipation factor) having lower loss of high-frequency signals than the motherboard 91 (see FIG. 3), on which the electronic circuit module 10 is mounted. This achieves further suppression of the transmission loss occurring due to the data transmission line Lop and the transmission loss occurring due to the information processing bus Lpm.

The power supply line-for-processor Lpwp, the power supply line-for-memory Lpwm, and the power supply line-for-photoelectric-conversion-unit Lpwo are formed in the second substrate 62. The power supply line-for-processor Lpwp, the power supply line-for-memory Lpwm, and the power supply line-for-photoelectric-conversion-unit Lpwo pass through the second substrate 62 in the thickness direction. The power supply line-for-processor Lpwp connects an electrode, on which the processor unit 20 on the surface of the second substrate 62 is mounted, to a processor power supply terminal on the underside surface of the second substrate 62. The power supply line-for-memory Lpwm connects an electrode, on which the memory 30 on the surface of the second substrate 62 is mounted, to a memory power supply terminal on the underside surface of the second substrate 62. The power supply line-for-photoelectric-conversion-unit Lpwo connects an electrode, on which the photoelectric conversion unit 40 on the surface of the second substrate 62 is mounted, to a photoelectric-conversion-unit power supply terminal on the underside surface of the second substrate 62.

The power supply line-for-processor Lpwp, the power supply line-for-memory Lpwm, and the power supply line-for-photoelectric-conversion-unit Lpwo can be straight as much as possible. In other words, these can be formed so that most portions of these extend in the thickness direction of the second substrate 62. The second substrate 62 has a thickness substantially smaller than the other dimensions. Thus, this configuration enables the power supply distances to be made short, achieving suppression of reduction of the power-supply efficiency. In addition, the portions, which extend in the thickness direction, of the power supply line-for-processor Lpwp, the power supply line-for-memory Lpwm, and the power supply line-for-photoelectric-conversion-unit Lpwo can have larger cross-sectional areas than the data transmission line Lop and the information processing bus Lpm, achieving improved power-supply efficiency.

The second substrate 62 and the power conversion unit 50 are mounted on a surface of the first substrate 61.

In the first substrate 61, multiple power supply lines Lpw are formed. The power supply lines Lpw, which are conductor patterns, connect electrodes, on which the power conversion unit 50 is mounted, to an electrode, on which the processor power supply terminal of the second substrate 62 is mounted, an electrode, on which the memory power supply terminal is mounted, and an electrode, on which the photoelectric-conversion-unit power supply terminal is mounted.

This configuration enables power supply from the power conversion unit 50 to the processor unit 20 to be performed only by using a conductor pattern (a power supply line Lpw) in the first substrate 61, which is smaller than the motherboard 91, and a conductor pattern (the power supply line-for-processor Lpwp) which extends in the thickness direction of the second substrate 62. Thus, the electronic circuit module 10 achieves highly efficient power supply to the processor unit 20.

Similarly, power supply from the power conversion unit 50 to the photoelectric conversion unit 40 may be performed only by using a conductor pattern (a power supply line Lpw) in the first substrate 61, which is smaller than the motherboard 91, and a conductor pattern (the power supply line-for-photoelectric-conversion-unit Lpwo) which extends in the thickness direction of the second substrate 62. Thus, the electronic circuit module 10 achieves highly efficient power supply to the photoelectric conversion unit 40.

Similarly, power supply from the power conversion unit 50 to the memory 30 may be performed only by using a conductor pattern (a power supply line Lpw) in the first substrate 61, which is smaller than the motherboard 91, and a conductor pattern (the power supply line-for-memory Lpwm) which extends in the thickness direction of the second substrate 62. Thus, the electronic circuit module 10 achieves highly efficient power supply to the memory 30.

The second substrate 62 and the power conversion unit 50 are mounted adjacent to each other. In other words, no other mount electronic components are mounted between the second substrate 62 and the power conversion unit 50. The second substrate 62 and the power conversion unit 50 are disposed close to each other. For example, the distance between the processor unit 20 on the second substrate 62 and the power conversion unit 50 can be equal to or less than the length of the long side of the processor unit 20 and the power conversion unit 50, and can be equal to or less than a half of the long side or the length of the short side. When the processor unit 20 and the power conversion unit 50 form a square in plan view, the distance is to be equal to or less than a side, and can be equal to or less than a side or a half of a side.

This enables the power supply distances from the power conversion unit 50 to the processor unit 20, the memory 30, and the photoelectric conversion unit 40 to be made short, achieving suppression of reduction of the power-supply efficiency.

The first substrate 61 is formed of a material, which is easily available and with which manufacturing is easy, compared with the second substrate 62.

Multiple external connection terminals BP61 are formed on the underside surface of the first substrate 61.

The width and cross-sectional area of each of the power supply lines Lpw can be large as much as possible. This achieves suppression of reduction of the power-supply efficiency. In particular, in this configuration, the first substrate 61 has no conductor patterns of the data communication system, and has only the power supply lines Lpw formed therein. Therefore, the power supply lines Lpw are easy to form into predetermined wiring and shape. That is, compared with a configuration of the related art in which power supply lines are formed in the same substrate (for example, a motherboard) as the conductor pattern of a data communication system, the width and cross-sectional area of each power supply line Lpw are easy to be made large, and the length is easy to be made short. Therefore, the electronic circuit module 10 achieves the power supply lines Lpw having high power-supply efficiency.

In particular, the processor unit 20 is required to have a low voltage and a high current. Therefore, the configuration in which the power supply line Lpw and the power supply line-for-processor Lpwp, which connect the power conversion unit 50 to the processor unit 20, are short enables the electronic circuit module 10 to achieve higher efficient power supply.

In addition, the configuration in which the power supply line Lpw extends straight from the power conversion unit 50 to the processor unit 20 in the direction orthogonal to the thickness direction of the first substrate 61 and in which the power supply line-for-processor Lpwp extends straight in the thickness direction of the second substrate 62 causes the distance of the line, which connects the power conversion unit 50 to the processor unit 20, to be the shortest. This achieves further suppression of the power transmission loss and enables the electronic circuit module 10 to achieve higher efficient power supply.

In the first substrate 61, power supply input lines 652 are formed. The power supply input lines 652 connect electrodes, on which the power conversion unit 50 is mounted, to external connection terminals BP61 for power supply input. The power supply input lines 652 extend in the thickness direction of the first substrate 61. The power supply input lines 652 can be straight as much as possible. In other words, these can be formed so that most portions of the power supply input lines 652 extend in the thickness direction of the first substrate 61. The thickness of the first substrate 61 is substantially smaller than the other dimensions. Thus, such a configuration enables the power supply distance to be made short. This achieves suppression of reduction of the power input efficiency from the outside. The portions of the power supply input lines 652, which extend in the thickness direction, can have a large cross-sectional area. This improves the power input efficiency from the outside.

Such a configuration enables the electronic circuit module 10 to achieve high information transmission efficiency and high power-supply efficiency.

As illustrated in FIG. 3, the electronic circuit module 10 having this configuration is mounted on the motherboard 91. The motherboard 91 has a power supply or the like which converts power from a commercial power supply or the like to direct-current power. From this power supply, power is supplied to the electronic circuit module 10 through a power line 92P in the motherboard 91.

On a surface of the motherboard 91, multiple mount lands 93 are formed, and a socket mechanism 94 is provided.

The external connection terminals BP61 of the electronic circuit module 10 are in contact with mount lands 93 of the motherboard 91. In this state, the socket mechanism 94 presses, for fixing, the electronic circuit module 10 onto the surface of the motherboard 91. Thus, the electronic circuit module 10 and the motherboard 91 are connected to each other so as to be stable electrically and mechanically.

Alternatively, the electronic circuit module 10 may be mounted on the motherboard 91 by using a conductive jointing material such as solder. However, the socket mechanism 94 described above facilitates attachment, replacement, and the like of the electronic circuit module 10. In the present embodiment, the form using the socket mechanism 94 is illustrated. A different structure may be used as long as the structure enables the electronic circuit module 10 to be fixed so as to be attachable to and detachable from the motherboard 91.

In the electronic circuit module 10, the processor unit 20, the memory 30, the photoelectric conversion unit 40, and the power conversion unit 50 are mounted by using solder or the like. For these configurations, an attachable/detachable structure using a socket mechanism 94 or the like may be employed. Further, for the structure in which the second substrate 62 is fixed onto the first substrate 61, an attachable/detachable structure using a socket mechanism 94 or the like may be employed.

In the embodiment described above, the form in which the processor unit 20 and the photoelectric conversion unit 40 are connected to each other only by using a conductor pattern in the electronic circuit module 10 is described. Alternatively, the processor unit 20 may be connected complementarily to a different photoelectric conversion unit, which is mounted on the motherboard 91, as well as to the photoelectric conversion unit 40 in the electronic circuit module 10.

Similarly, in the embodiment described above, the form in which the processor unit 20 and the power conversion unit 50 are connected to each other only by a conductor pattern in the electronic circuit module 10 is described. Alternatively, the processor unit 20 may be connected complementarily to a different power conversion unit, which is mounted on the motherboard 91, as well as to the power conversion unit 50 in the electronic circuit module 10.

In the embodiment described above, the form in which the photoelectric conversion unit 40 and the power conversion unit 50 are connected to each other only by using a conductor pattern in the electronic circuit module 10 is described. Alternatively, the photoelectric conversion unit 40 may be connected complementarily to a different power conversion unit, which is mounted on the motherboard 91, as well as to the power conversion unit 50 in the electronic circuit module 10.

### Second Embodiment

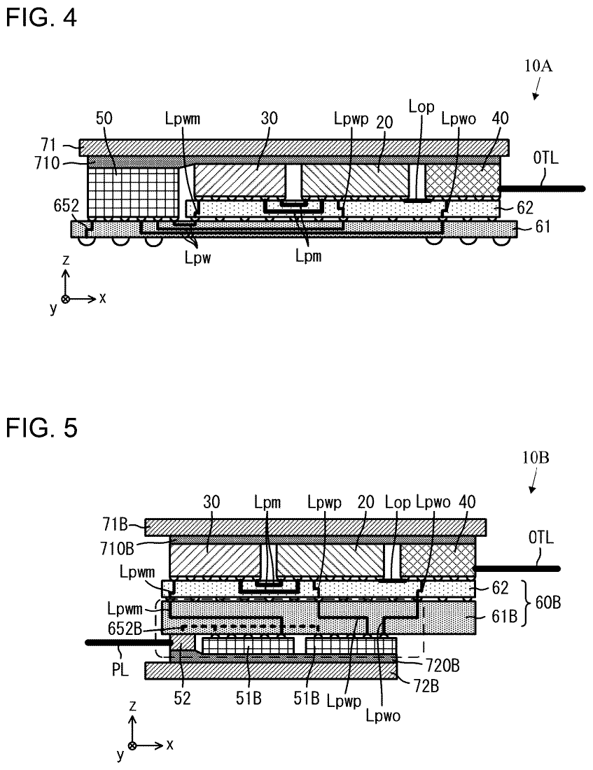

An electronic circuit module according to a second embodiment of the present disclosure will be described by referring to a drawing. FIG. 4 is a side view of the configurations of an electronic circuit module according to the second embodiment.

As illustrated in FIG. 4, an electronic circuit module 10A according to the second embodiment is different from the electronic circuit module 10 according to the first embodiment in that a heat dissipation mechanism is included. The other configurations of the electronic circuit module 10A are substantially the same as those of the electronic circuit module 10, and will not be described.

The electronic circuit module 10A includes a heat dissipation plate 71 and a thermal conductive gel 710. The heat dissipation plate 71 is a flat plate formed of a material having a high thermal conductivity, such as a metal. The heat dissipation plate 71 overlaps the processor unit 20, the memory 30, the photoelectric conversion unit 40, and the power conversion unit 50 in plan view.

The heat dissipation plate 71 connects with the processor unit 20, the memory 30, the photoelectric conversion unit 40, and the power conversion unit 50 with the thermal conductive gel 710 interposed in between.

This configuration enables the electronic circuit module 10 to dissipate heat from the processor unit 20, the memory 30, the photoelectric conversion unit 40, and the power conversion unit 50 to the outside effectively.

The thermal conductive gel 710 may be omitted. However, even when the top surfaces of the components, from which heat is to be dissipated, are not flush with each other (for example, when the top surface of the power conversion unit 50 in FIG. 4 is lower than the other top surfaces), the thermal conductive gel 710 enables the common heat dissipation plate 71 to connect with the units through a path with high heat dissipation.

In the description above, the processor unit 20, the memory 30, the photoelectric conversion unit 40, and the power conversion unit 50 use the heat dissipation plate 71 as a common plate. Alternatively, each unit may be provided with an individual heat dissipation plate. When heat dissipation plates are provided individually, at least heat dissipation plates particularly for the processor unit 20 and the power conversion unit 50 which have high heat generation can be provided.

Use of the common heat dissipation plate 71 enables the number of components of the electronic circuit module 10A to be decreased, causing the heat dissipation area to be easily made larger.

### Third Embodiment

An electronic circuit module according to a third embodiment of the present disclosure will be described by referring to a drawing. FIG. 5 is a side view of the configuration of an electronic circuit module according to the third embodiment.

As illustrated in FIG. 5, an electronic circuit module 10B according to the third embodiment is different from the electronic circuit module 10 according to the first embodiment in the configuration of the power supply system. The other configurations of the electronic circuit module 10B are substantially the same as those of the electronic circuit module 10, and will not be described.

The electronic circuit module 10B includes a package substrate 60B. The package substrate 60B includes a first substrate 61B and the second substrate 62.

The first substrate 61B is formed of a material substantially the same as that of the first substrate 61 according to the first embodiment. The planar area of the first substrate 61B is substantially the same as that of the second substrate 62. On the underside surface of the first substrate 61B, that is, the opposite surface of the surface, on which the second substrate 62 is mounted, of the first substrate 61B, multiple power conversion units 51B are mounted.

The power conversion units 51B are provided in accordance with the components to which power is to be supplied. The electronic circuit module 10B includes a power conversion unit 51B for the memory 30 and a power conversion unit 51B for the processor unit 20 and the photoelectric conversion unit 40.

An external-power connector 52 is mounted on the underside surface of the first substrate 61B. The external-power connector 52 is connected to a power supply cable PL from the outside. Thus, the electronic circuit module 10B is supplied with power from the outside.

In plan view of the electronic circuit module 10B, the arrangement area of the power conversion units 51B overlaps the arrangement area of the processor unit 20, the memory 30, and the photoelectric conversion unit 40.

Therefore, the electronic circuit module 10B achieves a smaller planar area than the electronic circuit module 10.

In the configuration in FIG. 5, the form of connection with a motherboard using a connector or the like is described. Alternatively, a structure in which multiple terminal electrodes are formed in a side end portion of the package substrate 60B, and in which the terminal electrodes are inserted into connectors of a motherboard may be employed.

The electronic circuit module 10B includes a heat dissipation plate 71B, a heat dissipation plate 72B, a thermal conductive gel 710B, and a thermal conductive gel 720B.

The heat dissipation plate 71B thermally connects with the processor unit 20, the memory 30, and the photoelectric conversion unit 40 with the thermal conductive gel 710B interposed in between. Thus, heat from the processor unit 20, the memory 30, and the photoelectric conversion unit 40 is dissipated effectively.

The heat dissipation plate 72B thermally connects with the power conversion units 51B with the thermal conductive gel 720B interposed in between. Thus, heat from the power conversion units 51B is dissipated effectively.

In this configuration, the processor unit 20 and the power conversion units 51B, which are relatively highly exothermic, are provided with heat dissipation plates 71B and 72B separately. Thus, the electronic circuit module 10B achieves further higher heat dissipation efficiency. The heat dissipation plate 71B and the heat dissipation plate 72B are disposed on different sides with the package substrate 60B interposed in between. Thus, heat from the heat dissipation plate 71B and heat from the heat dissipation plate 72B are difficult to combine, improving the heat dissipation effect of the electronic circuit module 10B.

The electronic circuit module 10B is not necessarily mounted on the motherboard 91, enabling the electronic circuit module 10B to be used in more forms.

### Fourth Embodiment

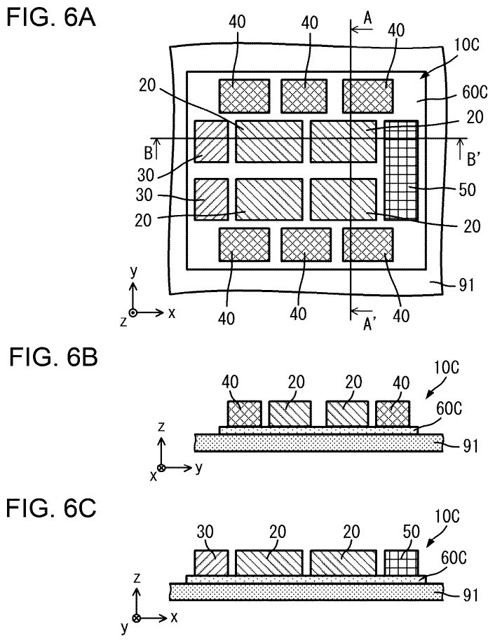

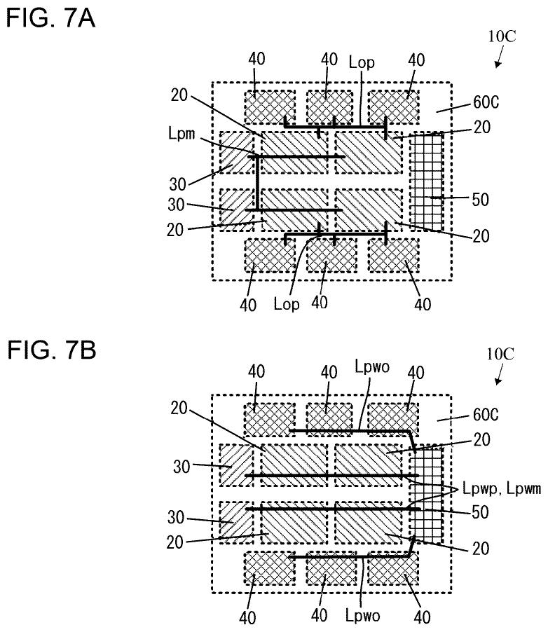

An electronic circuit module according to a fourth embodiment of the present disclosure will be described by referring to drawings. FIG. 6A is a plan view of the configuration of an electronic circuit module according to the fourth embodiment. FIG. 6B is a side view along A-A′ in FIG. 6A. FIG. 6C is a sectional view along B-B′ in FIG. 6A. FIG. 7A is a diagram illustrating an exemplary wiring pattern of a data communication system in an electronic circuit module according to the fourth embodiment. FIG. 7B is a diagram illustrating an exemplary wiring pattern of a power supply system in an electronic circuit module according to the fourth embodiment.

The components in each of the present embodiment (fourth embodiment) and its subsequent embodiments are substantially the same as those in the first embodiment except the contents described below, and will not be described. In the present embodiment and its subsequent embodiments, terminals of the components will not be illustrated.

As illustrated in FIGS. 6A to 6C, an electronic circuit module 10C includes multiple processor units 20, multiple memories 30, multiple photoelectric conversion units 40, the power conversion unit 50, and a package substrate 60C.

The processor units 20, the memories 30, the photoelectric conversion units 40, and the power conversion unit 50 are mounted on a first surface (surface) of the package substrate 60C. That is, the processor units 20, the memories 30, the photoelectric conversion units 40, and the power conversion unit 50 are mounted on the single common package substrate 60C. In the area in which at least the processor units 20, the memories 30, and the photoelectric conversion units 40 are mounted, the package substrate 60C is formed of a material having lower loss of high-frequency signals than the motherboard 91.

A second surface (underside surface) of the package substrate 60C is mounted on the motherboard 91.

The processor units 20 are disposed in the center of the first surface. The memories 30 and the power conversion unit 50 are disposed so that the arrangement area of the processor units 20 is interposed in between in a first direction (the x-axis direction in FIG. 6A) parallel to the first surface. The arrangement area of the processor units 20 and the arrangement area of the memories 30 are adjacent to and close to each other. The arrangement area of the processor units 20 and the power conversion unit 50 are adjacent to and close to each other.

The photoelectric conversion units 40 are disposed so that the arrangement area of the processor units 20 is interposed in between in a second direction (the y-axis direction in FIG. 6A), which is parallel to the first surface and is orthogonal to the first direction (the x-axis direction in FIG. 6A). The arrangement area of the processor units 20 is adjacent to and close to the photoelectric conversion units 40.

As illustrated in FIG. 7A, this configuration enables the electronic circuit module 10C to have reduction in length of data transmission lines Lop (lines connecting the processor units 20 to the photoelectric conversion units 40). In addition, the electronic circuit module 10C achieves a simple, easy wiring configuration of the data transmission lines Lop. Therefore, the electronic circuit module 10C achieves suppression of the transmission loss and delay occurring due to the data transmission lines Lop.

In addition, the electronic circuit module 10C enables the information processing bus Lpm (a line connecting the processor units 20 to the memories 30) to be made short. The electronic circuit module 10C achieves a simple, easy wiring configuration of the information processing bus Lpm. Therefore, the electronic circuit module 10C achieves suppression of the transmission loss and delay occurring due to the information processing bus Lpm.

As illustrated in FIG. 7B, the electronic circuit module 10C enables the power supply line-for-processor Lpwp, the power supply line-for-memory Lpwm, and power supply lines-for-photoelectric-conversion-unit Lpwo, which extend from the power conversion unit 50, to be made short, achieving a simple configuration. Therefore, the electronic circuit module 10C achieves increase of the power-supply efficiency.

In this configuration, the memories 30 and the power conversion unit 50 are spaced with the arrangement area of the processor units 20 interposed in between. Thus, the electronic circuit module 10C achieves suppression of superposition of power-supply noise on the memories 30.

### Fifth Embodiment

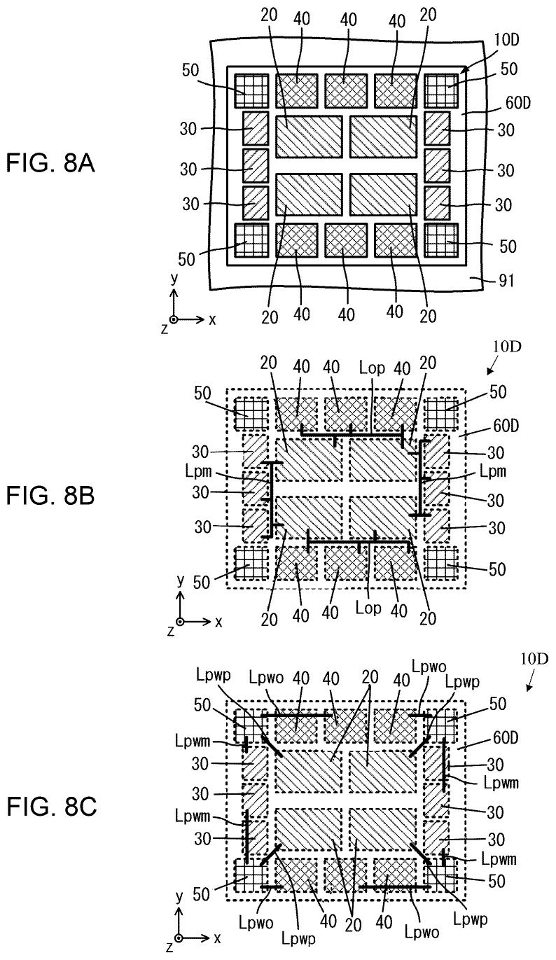

An electronic circuit module according to a fifth embodiment of the present disclosure will be described by referring to drawings. FIG. 8A is a plan view of the configuration of an electronic circuit module according to the fifth embodiment. FIG. 8B is a diagram illustrating an exemplary wiring pattern of a data communication system in an electronic circuit module according to the fifth embodiment. FIG. 8C is a diagram illustrating an exemplary wiring pattern of a power supply system in an electronic circuit module according to the fifth embodiment.

As illustrated in FIGS. 8A, 8B, and 8C, an electronic circuit module 10D according to the fifth embodiment is different from the electronic circuit module 10C according to the fourth embodiment in the arrangement pattern and wiring pattern of the components. The other configurations of the electronic circuit module 10D are substantially the same as those of the electronic circuit module 10C, and will not be described.

The memories 30 are disposed on both the sides in a first direction (the x-axis direction in FIG. 8A) of a package substrate 60D, with the arrangement area of the processor units 20 interposed in between. The photoelectric conversion units 40 are disposed on both the sides in a second direction (the y-axis direction in FIG. 8A) of the package substrate 60D, with the arrangement area of the processor units 20 interposed in between.

Multiple power conversion units 50 are disposed in the outer corners formed by arrangement of the memories 30 and the photoelectric conversion units 40.

The processor units 20 are adjacent to and close to the memories 30 in the first direction. The processor units 20 are adjacent to and close to the photoelectric conversion units 40 in the second direction.

As illustrated in FIG. 8B, this configuration enables the electronic circuit module 10D to have reduction in length of the data transmission lines Lop and the information processing buses Lpm. In addition, the electronic circuit module 10D achieves a simple, easy wiring configuration of the data transmission lines Lop and the information processing buses Lpm. Therefore, the electronic circuit module 10D achieves suppression of the transmission loss and delay occurring due to the data transmission lines Lop and the information processing buses Lpm.

Each of the power conversion units 50 is adjacent to or close to a processor unit 20, a memory 30, and a photoelectric conversion unit 40. As illustrated in FIG. 8C, this enables the electronic circuit module 10D to have reduction in length of power supply lines-for-processor Lpwp, power supply lines-for-memory Lpwm, and the power supply lines-for-photoelectric-conversion-unit Lpwo, which extend from the power conversion units 50, achieving a simple configuration. Therefore, the electronic circuit module 10D achieves high power-supply efficiency.

The area efficiency of the processor units 20, the memories 30, the photoelectric conversion units 40, and the power conversion units 50 with respect to the package substrate 60D is good. This achieves a reduction in size of the electronic circuit module 10D.

The power conversion units 50 are disposed in the corners of the arrangement area of the processor units 20, the memories 30, and the photoelectric conversion units 40. Therefore, influence of heat from the power conversion units 50 on the processor units 20 is suppressed, and the electronic circuit module 10D easily dissipates the heat to the outside.

### Sixth Embodiment

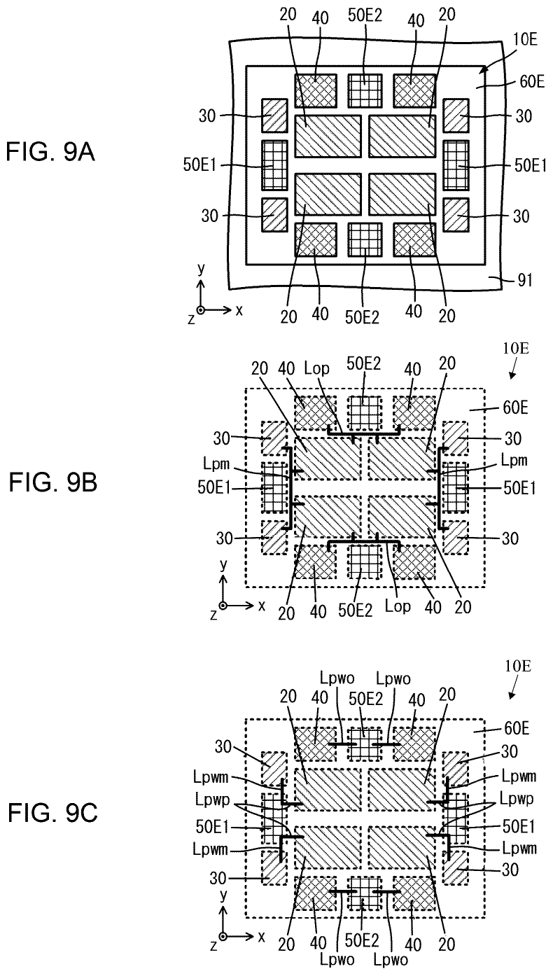

An electronic circuit module according to a sixth embodiment of the present disclosure will be described by referring to drawings. FIG. 9A is a plan view of the configuration of an electronic circuit module according to the sixth embodiment. FIG. 9B is a diagram illustrating an exemplary wiring pattern of a data communication system in an electronic circuit module according to the sixth embodiment. FIG. 9C is a diagram illustrating an exemplary wiring pattern of a power supply system in an electronic circuit module according to the sixth embodiment.

As illustrated in FIGS. 9A, 9B, and 9C, an electronic circuit module 10E according to the sixth embodiment is different from the electronic circuit module 10C according to the fourth embodiment in the arrangement pattern and wiring pattern of the components. The other configurations of the electronic circuit module 10E are substantially the same as those of the electronic circuit module 10C, and will not be described.

The memories 30 are disposed on both the sides in a first direction (the x-axis direction in FIG. 9A) of a package substrate 60E, with the arrangement area of the processor units 20 interposed in between. The photoelectric conversion units 40 are disposed on both the sides in a second direction (the y-axis direction in FIG. 9A) of the package substrate 60E, with the arrangement area of the processor units 20 interposed in between.

Power conversion units 50E1 are each disposed between memories 30, which are arranged in the second direction, so as to be adjacent to and close to the memories 30. Power conversion units 50E2 are each disposed between photoelectric conversion units 40, which are arranged in the first direction, so as to be adjacent to and close to the photoelectric conversion units 40.

The processor units 20 are adjacent to and close to the memories 30 in the first direction. The processor units 20 are adjacent to and close to the photoelectric conversion units 40 in the second direction. The processor units 20 are adjacent to and close to the power conversion units 50E1 in the first direction. The processor units 20 are adjacent to and close to the power conversion units 50E2 in the second direction.

As illustrated in FIG. 9B, this configuration enables the electronic circuit module 10E to have reduction in length of the data transmission lines Lop and the information processing buses Lpm. In addition, the electronic circuit module 10E achieves a simple, easy wiring configuration of the data transmission lines Lop and the information processing buses Lpm. Therefore, the electronic circuit module 10E achieves suppression of the transmission loss and delay occurring due to the data transmission lines Lop and the information processing buses Lpm.

Each of the power conversion units 50E1 and 50E2 is adjacent to or close to processor units 20, memories 30, and photoelectric conversion units 40. As illustrated in FIG. 9C, this enables the electronic circuit module 10E to have reduction in length of the power supply lines-for-processor Lpwp, the power supply lines-for-memory Lpwm, and the power supply lines-for-photoelectric-conversion-unit Lpwo, which extend from the power conversion units 50E1 and 50E2, achieving a simple configuration. Therefore, the electronic circuit module 10E achieves high power-supply efficiency.

In this configuration, the arrangement of the memories 30, the photoelectric conversion units 40, and the power conversion units 50E1 and 50E2 is good in symmetry. The electronic circuit module 10E achieves a configuration in which the wiring pattern of the data transmission lines Lop, the information processing buses Lpm, the power supply lines-for-processor Lpwp, the power supply lines-for-memory Lpwm, and the power supply lines-for-photoelectric-conversion-unit Lpwo is easy to be designed.

Memories 30 are disposed on both the sides of each power conversion unit 50E1; photoelectric conversion units 40 are disposed on both the sides of each power conversion unit 50E2. Therefore, the electronic circuit module 10E achieves symmetrization of power supply to the memories 30 and the photoelectric conversion units 40.

Further, the electronic circuit module 10E achieves separation and spacing between power supply from the power conversion units 50E1 to the memories 30 and that from the power conversion units 50E2 to the photoelectric conversion units 40. Thus, the electronic circuit module 10E achieves suppression of interference between these power supply lines (the power supply lines-for-memory Lpwm and the power supply lines-for-photoelectric-conversion-unit Lpwo).

Further, the electronic circuit module 10E achieves separation of the power supply lines-for-photoelectric-conversion-unit Lpwo from the other power supply lines, and achieves suppression of superposition of noise on the power supply lines-for-photoelectric-conversion-unit Lpwo.

### Seventh Embodiment

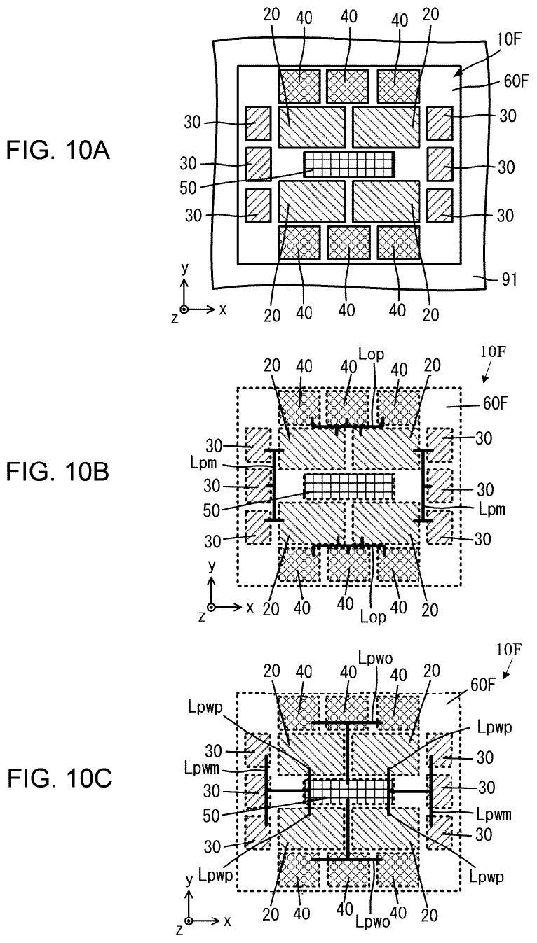

An electronic circuit module according to a seventh embodiment of the present disclosure will be described by referring to drawings. FIG. 10A is a plan view of the configuration of an electronic circuit module according to the seventh embodiment. FIG. 10B is a diagram illustrating an exemplary wiring pattern of a data communication system in an electronic circuit module according to the seventh embodiment. FIG. 10C is a diagram illustrating an exemplary wiring pattern of a power supply system in an electronic circuit module according to the seventh embodiment.

As illustrated in FIGS. 10A, 10B, and 10C, an electronic circuit module 10F according to the seventh embodiment is different from the electronic circuit module 10C according to the fourth embodiment in the arrangement pattern and wiring pattern of the components. The other configurations of the electronic circuit module 10F are substantially the same as those of the electronic circuit module 10C, and will not be described.

The power conversion unit 50 is disposed in the center of a first surface of a package substrate 60F. The processor units 20 are disposed so as to surround the power conversion unit 50. The processor units 20 are adjacent to and close to the power conversion unit 50.

The memories 30 are disposed on both the sides in a first direction (the x-axis direction in FIG. 10A) of the package substrate 60F, with the arrangement area of the power conversion unit 50 and the processor units 20 interposed in between. The photoelectric conversion units 40 are disposed on both the sides in a second direction (the y-axis direction in FIG. 10A) of the package substrate 60F, with the arrangement area of the power conversion unit 50 and the processor units 20 interposed in between.

The processor units 20 are adjacent to and close to the memories 30 in the first direction. The processor units 20 are adjacent to and close to the photoelectric conversion units 40 in the second direction.

As illustrated in FIG. 9B, this configuration enables the electronic circuit module 10F to have reduction in length of the data transmission lines Lop and the information processing buses Lpm. In addition, the electronic circuit module 10F achieves a simple, easy wiring configuration of the data transmission lines Lop and the information processing buses Lpm. Therefore, the electronic circuit module 10F achieves suppression of the transmission loss and delay occurring due to the data transmission lines Lop and the information processing buses Lpm.

In this configuration, the arrangement of the memories 30, the photoelectric conversion units 40, and the power conversion units 50 is good in symmetry. Thus, the electronic circuit module 10E achieves a configuration in which the wiring pattern of the data transmission lines Lop and the information processing buses Lpm is easily designed. Further, the power conversion unit 50, which is located in the center, enables a variety of wiring pattern of the power supply lines-for-processor Lpwp, the power supply lines-for-memory Lpwm, and the power supply lines-for-photoelectric-conversion-unit Lpwo to be achieved. That is, in accordance with the power supply specifications of the memories 30, the photoelectric conversion units 40, and the power conversion units 50, power supply lines to the respective components may be provided separately or a common power supply line to components may be provided. When separate lines are provided, the electronic circuit module 10F achieves improvement of quality of power supply to the memories 30, the photoelectric conversion units 40, and the power conversion units 50. When a common power supply line is provided for components, the electronic circuit module 10F achieves a small space for power supply and a reduction in size.

In this configuration, the power conversion unit 50 are adjacent to and close to the processor units 20. This enables the electronic circuit module 10F to have reduction in length of the power supply lines-for-processor Lpwp, and to achieve high efficiency of power supply to the processor units 20.

### Eighth Embodiment

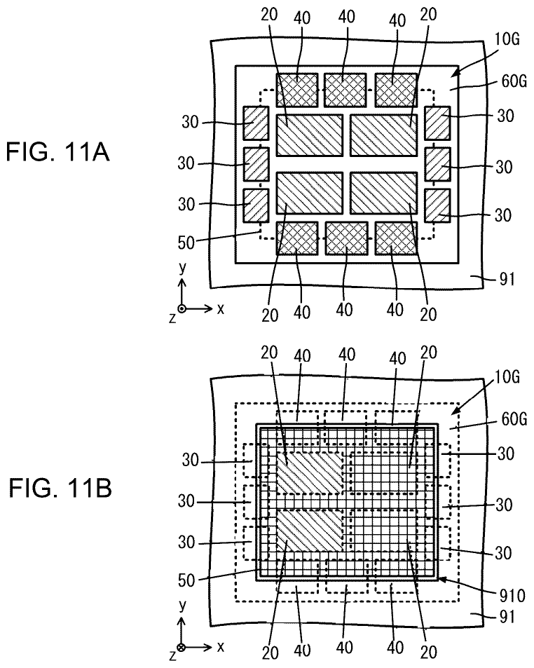

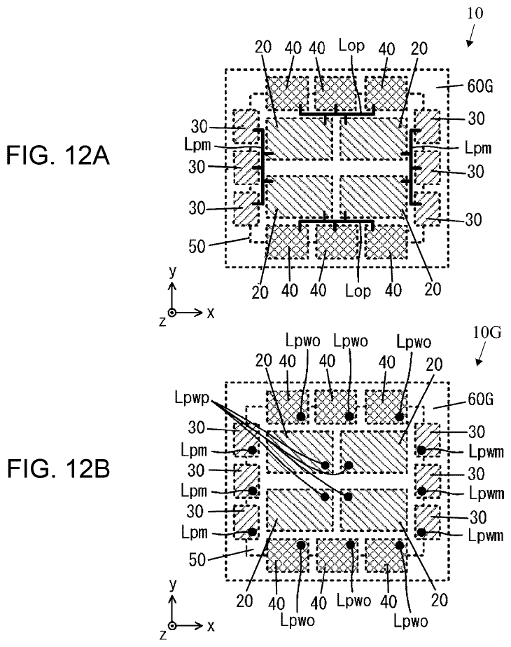

An electronic circuit module according to an eighth embodiment of the present disclosure will be described by referring to drawings. FIGS. 11A and 11B are plan views of the configuration of an electronic circuit module according to the eighth embodiment. FIG. 11A illustrates the first surface side; FIG. 11B illustrates the second surface side. FIG. 12A is a diagram illustrating an exemplary wiring pattern of a data communication system in an electronic circuit module according to the eighth embodiment. FIG. 12B is a diagram illustrating an exemplary wiring pattern of a power supply system in an electronic circuit module according to the eighth embodiment.

As illustrated in FIGS. 11A and 11B, an electronic circuit module 10G according to the eighth embodiment is different from the electronic circuit module 10C according to the fourth embodiment in the arrangement pattern and wiring pattern of the components. The other configurations of the electronic circuit module 10G are substantially the same as those of the electronic circuit module 10C, and will not be described.

The processor units 20 are disposed in the center of the first surface of a package substrate 60G. The memories 30 are disposed on both the sides in a first direction (the x-axis direction in FIG. 11A) of the package substrate 60G, with the arrangement area of the processor units 20 interposed in between. The photoelectric conversion units 40 are disposed on both the sides in a second direction (the y-axis direction in FIG. 11A) of the package substrate 60G, with the arrangement area of the processor units 20 interposed in between.

The processor units 20 are adjacent to and close to the memories 30 in the first direction. The processor units 20 are adjacent to and close to the photoelectric conversion units 40 in the second direction.

The power conversion unit 50 is disposed on the second surface of the package substrate 60G. When viewed in a direction (the z-axis direction in FIG. 11B) orthogonal to the first surface and the second surface, the power conversion unit 50 overlaps the processor units 20, the memories 30, and the photoelectric conversion units 40.

As illustrated in FIG. 12A, this configuration enables the electronic circuit module 10G to have reduction in length of the data transmission lines Lop and the information processing buses Lpm. In addition, the electronic circuit module 10G achieves a simple, easy wiring configuration of the data transmission lines Lop and the information processing buses Lpm. Therefore, the electronic circuit module 10G achieves suppression of the transmission loss and delay occurring due to the data transmission lines Lop and the information processing buses Lpm.

In this configuration, the power supply lines-for-processor Lpwp, the power supply lines-for-memory Lpwm, and the power supply lines-for-photoelectric-conversion-unit Lpwo are formed by using a conductor pattern extending in the thickness direction of the package substrate 60G. This enables the electronic circuit module 10G to have reduction in length of the power supply lines-for-processor Lpwp, the power supply lines-for-memory Lpwm, and the power supply lines-for-photoelectric-conversion-unit Lpwo. Therefore, the electronic circuit module 10G achieves high power-supply efficiency.

This configuration achieves a large area of the power conversion unit 50. Therefore, the electronic circuit module 10G achieves greater freedom in design of the power conversion unit 50.

### Ninth Embodiment

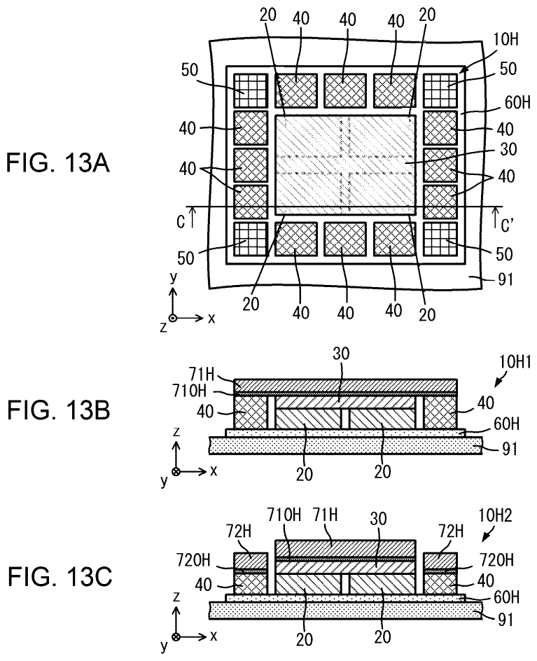

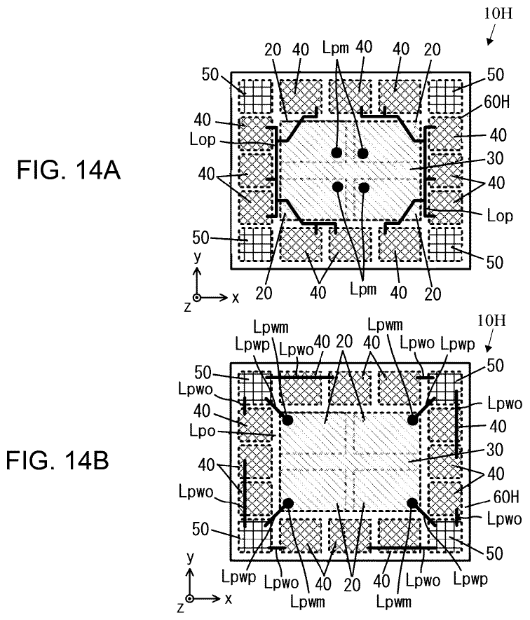

An electronic circuit module according to a ninth embodiment of the present disclosure will be described by referring to drawings. FIG. 13A is a plan view of the configuration of an electronic circuit module according to the ninth embodiment. FIGS. 13B and 13C are diagrams illustrating different examples of the cross section along C-C′ in FIG. 13A. FIG. 13A illustrates the state in which a heat dissipation plate and a thermal conductive gel are excluded. FIG. 14A is a diagram illustrating an exemplary wiring pattern of a data communication system in an electronic circuit module according to the ninth embodiment. FIG. 14B is a diagram illustrating an exemplary wiring pattern of a power supply system in an electronic circuit module according to the ninth embodiment.

As illustrated in FIGS. 13A, 13B, and 13C, an electronic circuit module 10H according to the ninth embodiment is different from the electronic circuit module 10C according to the fourth embodiment in the arrangement pattern and wiring pattern of the components. The other configurations of the electronic circuit module 10H are substantially the same as those of the electronic circuit module 10C, and will not be described.

The processor units 20 are disposed in the center of a first surface of a package substrate 60H. The photoelectric conversion units 40 are disposed around the arrangement area of the processor units 20. The arrangement area of the processor units 20 is adjacent to and close to the photoelectric conversion units 40 in directions parallel to the first surface.

The power conversion units 50 are disposed in the outer corners formed by the arrangement of the photoelectric conversion units 40.

The memory 30 are disposed above the processor units 20 so as to overlie the arrangement area of the processor units 20. In other words, the memory 30 is disposed opposite the package substrate 60H with the processor units 20 interposed in between. The memory 30 and the processor units 20 are adjacent to and close to each other in a direction orthogonal to the first surface.

As illustrated in FIG. 14A, this configuration enables the electronic circuit module 10H to have reduction in length of the data transmission lines Lop and the information processing buses Lpm. In addition, in the electronic circuit module 10H, the main wiring direction of the data transmission lines Lop is orthogonal to that of the information processing buses Lpm, achieving easy wiring. As a result, the wiring of the data transmission lines Lop and that of the information processing buses Lpm may be made short. Therefore, the electronic circuit module 10H achieves suppression of the transmission loss and delay occurring due to the data transmission lines Lop and the information processing buses Lpm.

In plan view of the electronic circuit module 10H, the power conversion units 50 are each adjacent to or close to a processor unit 20, a memory 30, and a photoelectric conversion unit 40. As illustrated in FIG. 14B, this enables the electronic circuit module 10H to have reduction in length of the power supply lines-for-processor Lpwp, the power supply lines-for-memory Lpwm, and the power supply lines-for-photoelectric-conversion-unit Lpwo, which extend from the power conversion units 50, achieving a simple configuration. Therefore, the electronic circuit module 10H achieves high power-supply efficiency.

This configuration achieves a large planar area of the memory 30. Therefore, without necessarily an increase of the entire shape, the electronic circuit module 10H achieves a large capacitance of the memory 30.

As illustrated in FIGS. 13B and 13C, this configuration enables the configuration of the heat dissipation plate to be adjusted appropriately through the height of the photoelectric conversion units 40.

In the case of FIG. 13B, the height of a photoelectric conversion unit 40 is substantially the same as that of a processor unit 20 and the memory 30. In this case, the electronic circuit module 10H includes a heat dissipation plate 71H. The heat dissipation plate 71H overlies the photoelectric conversion units 40 and the memory 30, and thermally connects with the photoelectric conversion units 40 and the memory 30 through a thermal conductive gel 710H.

In the case of FIG. 13C, the height of a photoelectric conversion unit 40 is substantially the same as that of a processor unit 20. In this case, the electronic circuit module 10H includes the heat dissipation plate 71H and a heat dissipation plate 72H. The heat dissipation plate 71H overlies the memory 30, and thermally connects with the memory 30 through the thermal conductive gel 710H. The heat dissipation plate 72H overlies the photoelectric conversion units 40, and thermally connects with the photoelectric conversion units 40 through a thermal conductive gel 720H.

<1> An electronic circuit module mounted on a motherboard having a power supply source, the electronic circuit module comprising:
a photoelectric conversion unit that performs conversion between an optical signal and an electric signal;
a processor unit that performs computational processing by using the electric signal;
a power conversion unit that converts power from the power supply source and that supplies power to the photoelectric conversion unit and the processor unit; and
a package substrate that has the photoelectric conversion unit, the processor unit, and the power conversion unit which are mounted thereon,
wherein the photoelectric conversion unit, the processor unit, and the power conversion unit are connected only through a conductor pattern formed on/in the package substrate.

<2> The electronic circuit module according to <1>,
wherein the package substrate includes
   a first substrate that has the power conversion unit mounted thereon, and
   a second substrate that has the photoelectric conversion unit and the processor unit which are mounted thereon and that is mounted on the first substrate.

<3> An electronic circuit module mounted on a motherboard having a power supply source, the electronic circuit module comprising:
a photoelectric conversion unit that performs conversion between an optical signal and an electric signal;
a processor unit that performs computational processing by using the electric signal;
a power conversion unit that converts power from the power supply source and that supplies power to the photoelectric conversion unit and the processor unit; and
a package substrate that has the photoelectric conversion unit, the processor unit, and the power conversion unit which are mounted thereon and that has a portion having lower loss of a high-frequency signal than the motherboard.

<4> The electronic circuit module according to <3>,
wherein the package substrate includes
   a first substrate that has the power conversion unit mounted thereon, and
   a second substrate that has the photoelectric conversion unit and the processor unit which are mounted thereon, and that is mounted on the first substrate, and
wherein the first substrate's loss of the high-frequency signal is lower than the motherboard's loss of the high-frequency signal.

<5> The electronic circuit module according to any of <1> to <4>,
wherein the photoelectric conversion unit and the processor unit are supplied with power from the power conversion unit which is a common unit.

<6> The electronic circuit module according to <5>,
wherein the photoelectric conversion unit and the processor unit are supplied with power from the power conversion unit which is a single unit.

<7> The electronic circuit module according to any of <1> to <6>,
wherein the photoelectric conversion unit and the processor unit thermally connect with a shared heat dissipation plate.

<8> The electronic circuit module according to <7>,
wherein the photoelectric conversion unit, the processor unit, and the power conversion unit thermally connect with the shared heat dissipation plate.

<9> The electronic circuit module according to any of <1> to <8>,
wherein the package substrate is mounted by using a structure in which the package substrate is attachable to and detachable from the motherboard.

<10> The electronic circuit module according to <9>,
wherein the package substrate is provided with a socket mechanism on a mount surface of the motherboard.

<11> The electronic circuit module according to <9> or <10>,
wherein at least one of units is mounted by using a structure in which the at least one of units is attachable to and detachable from the package substrate, the units including the photoelectric conversion unit, the processor unit, and the power conversion unit.

<12> The electronic circuit module according to any of <1> to <4>, further comprising:
a memory that is connected to the processor unit,
wherein the photoelectric conversion unit, the processor unit, the power conversion unit, and the memory are mounted on a first surface of the package substrate,
wherein the processor unit is disposed in the center of the first surface,
wherein the memory and the power conversion unit are disposed in a first direction with the processor unit interposed in between, the first direction being parallel to the first surface, and
wherein a plurality of the photoelectric conversion units are disposed in a second direction with the processor unit interposed in between, the second direction being parallel to the first surface and being orthogonal to the first direction.

<13> The electronic circuit module according to any of <1> to <4>, further comprising:
a memory that is connected to the processor unit,
wherein the photoelectric conversion unit, the processor unit, the power conversion unit, and the memory are mounted on a first surface of the package substrate,
wherein the processor unit is disposed in the center of the first surface,
wherein a plurality of the memories are disposed in a first direction with the processor unit interposed in between, the first direction being parallel to the first surface,
wherein a plurality of the photoelectric conversion units are disposed in a second direction with the processor unit interposed in between, the second direction being parallel to the first surface and being orthogonal to the first direction, and
wherein a plurality of the power conversion units are disposed in outer corners formed by arrangement of the plurality of the memories and the plurality of the photoelectric conversion units.

<14> The electronic circuit module according to any of <1> to <4>, further comprising:
a memory that is connected to the processor unit,
wherein the photoelectric conversion unit, the processor unit, the power conversion unit, and the memory are mounted on a first surface of the package substrate,
wherein the processor unit is disposed in the center of the first surface,
wherein a plurality of the memories are disposed in a first direction with the processor unit interposed in between, the first direction being parallel to the first surface,
wherein a plurality of the photoelectric conversion units are disposed in a second direction with the processor unit interposed in between, the second direction being parallel to the first surface and being orthogonal to the first direction, and
wherein a plurality of the power conversion units are disposed between the plurality of the memories and between the plurality of the photoelectric conversion units.

<15> The electronic circuit module according to any of <1> to <4>, further comprising:
a memory that is connected to the processor unit,
wherein the photoelectric conversion unit, the processor unit, the power conversion unit, and the memory are mounted on a first surface of the package substrate,
wherein the power conversion unit is disposed in the center of the first surface,
wherein a plurality of the processor units are disposed so as to surround the power conversion unit,
wherein a plurality of the memories are disposed in a first direction with the processor unit and the power conversion unit which are interposed in between, the first direction being parallel to the first surface, and
wherein a plurality of the photoelectric conversion units are disposed in a second direction with the processor unit and the power conversion unit which are interposed in between, the second direction being parallel to the first surface and being orthogonal to the first direction.

<16> The electronic circuit module according to any of <1> to <4>, further comprising:
a memory that is connected to the processor unit,
wherein the photoelectric conversion unit, the processor unit, and the memory are mounted on a first surface of the package substrate,
wherein the power conversion unit is mounted on a second surface of the package substrate,
wherein, when viewed in a direction orthogonal to the first surface and the second surface, the power conversion unit overlaps the photoelectric conversion unit, the processor unit, and the memory at least partially.

<17> The electronic circuit module according to any of <1> to <4>, further comprising:
a memory that is connected to the processor unit,
wherein the photoelectric conversion unit, the processor unit, and the power conversion unit are mounted on a first surface of the package substrate,
wherein the processor unit is disposed in the center of the first surface,
wherein a plurality of the photoelectric conversion units are disposed so as to surround the processor unit,
wherein a plurality of the power conversion units are disposed in outer corners formed by arrangement of the plurality of the photoelectric conversion units, and
wherein, when viewed in a direction orthogonal to the first surface, the memory overlaps the processor unit, and is disposed opposite the package substrate, with the processor unit interposed in between.

### REFERENCE SIGNS LIST

10, 10A, 10B, 10C, 10D, 10E, 10F, 10G, 10H electronic circuit module
20 processor unit
30 memory
40 photoelectric conversion unit
50, 51B, 50E1, 50E2 power conversion unit
52 external-power connector
60, 60B, 60C, 60D, 60E, 60F, 60G, 60H package substrate
61, 61B first substrate
62 second substrate
71, 71B, 71H, 72B, 72H heat dissipation plate
91 motherboard
92P power line
93 mount land
94 socket mechanism
652 power supply input line
710, 710B, 710H, 720B, 720H thermal conductive gel
BP61 external connection terminal
Lop data transmission line
Lpm information processing bus
Lpw power supply line
Lpwm power supply line-for-memory
Lpwo power supply line-for-photoelectric-conversion-unit
Lpwp power supply line-for-processor
OTL optical waveguide
PL power supply cable

1. An electronic circuit module mounted on a motherboard having a power supply source, the electronic circuit module comprising:
a photoelectric converter configured to convert an optical signal to an electric signal;
a processor configured to perform computational processing by using the electric signal;
a power converter configured to convert power from the power supply source and to supply the converted power to the photoelectric converter and to the processor; and
a package substrate on which the photoelectric converter, the processor, and the power converter are mounted,
wherein the photoelectric converter, the processor, and the power converter are connected only through a conductor pattern on or in the package substrate.

2. The electronic circuit module according to claim 1, wherein the package substrate comprises:
a first substrate on which the power converter is mounted, and
a second substrate on which the photoelectric converter and the processor are mounted, and that is mounted on the first substrate.

3. An electronic circuit module mounted on a motherboard having a power supply source, the electronic circuit module comprising:
a photoelectric converter configured to convert an optical signal to an electric signal;
a processor configured to perform computational processing by using the electric signal;
a power converter configured to convert power from the power supply source and to supply the converted power to the photoelectric converter and to the processor; and
a package substrate on which the photoelectric converter, the processor, and the power converter are mounted, and that has a portion having a lower loss of a high-frequency signal than the motherboard.

4. The electronic circuit module according to claim 3,
wherein the package substrate comprises:
a first substrate on which the power converter is mounted, and
a second substrate on which the photoelectric converter and the processor are mounted, and that is mounted on the first substrate, and
wherein the loss of the high-frequency signal of the portion of the first substrate is lower than a loss of the high-frequency signal of the motherboard.

5. The electronic circuit module according to claim 1, wherein the power converter is common to the photoelectric converter and the processor.

6. The electronic circuit module according to claim 5, wherein the power converter is a single unit.

7. The electronic circuit module according to claim 1, wherein the photoelectric converter and the processor thermally connect with a shared heat dissipation plate.

8. The electronic circuit module according to claim 7, wherein the photoelectric converter, the processor, and the power converter thermally connect with the shared heat dissipation plate.

9. The electronic circuit module according to claim 1, wherein the package substrate is mounted such that the package substrate is attachable to and detachable from the motherboard.

10. The electronic circuit module according to claim 9, wherein the package substrate comprises a socket mechanism on a mount surface of the motherboard.

11. The electronic circuit module according to claim 9, wherein the photoelectric converter, the processor, or the power converter is mounted such that the photoelectric converter, the processor, or the power converter is attachable to and detachable from the package substrate.

12. The electronic circuit module according to claim 1, further comprising:
memory that is connected to the processor; and
a plurality of the photoelectric converters,
wherein the plurality of the photoelectric converters, the processor, the power converter, and the memory are mounted on a first surface of the package substrate,
wherein the processor is in the center of the first surface,
wherein the memory and the power converter are arranged in a first direction with the processor interposed between the memory and the power converter, the first direction being parallel to the first surface, and
wherein a plurality of the photoelectric converters are arranged in a second direction with the processor interposed between the plurality of photoelectric converters, the second direction being parallel to the first surface and being orthogonal to the first direction.

13. The electronic circuit module according to claim 1, further comprising:
a plurality of memories that are connected to the processor;
a plurality of the photoelectric converters; and
a plurality of the power converters,
wherein the plurality of the photoelectric converters, the processor, the plurality of the power converters, and the plurality of the memories are mounted on a first surface of the package substrate,
wherein the processor is in the center of the first surface,
wherein the plurality of the memories are arranged in a first direction with the processor interposed between the plurality of memories, the first direction being parallel to the first surface,
wherein the plurality of the photoelectric converters are arranged in a second direction with the processor interposed between the plurality of the photoelectric converters, the second direction being parallel to the first surface and being orthogonal to the first direction, and
wherein the plurality of the power converters are arranged in outer corners formed by arrangement of the plurality of the memories and the plurality of the photoelectric converters.

14. The electronic circuit module according to claim 1, further comprising:
a plurality of memories that are connected to the processor;
a plurality of the photoelectric converters; and
a plurality of the power converters,
wherein the plurality of the photoelectric converters, the processor, the plurality of the power converters, and the plurality of the memories are mounted on a first surface of the package substrate,
wherein the processor is in the center of the first surface,
wherein a plurality of the memories are arranged in a first direction with the processor interposed between the plurality of the memories, the first direction being parallel to the first surface,
wherein the plurality of the photoelectric converters are arranged in a second direction with the processor interposed between the plurality of photoelectric converters, the second direction being parallel to the first surface and being orthogonal to the first direction, and wherein the plurality of the power converters are arranged between the plurality of the memories and between the plurality of the photoelectric converters.

15. The electronic circuit module according to claim 1, further comprising:
a plurality of memories that are connected to the processor unit;
a plurality of the photoelectric converters; and
a plurality of the processors,
wherein the plurality of the photoelectric converters, the plurality of the processors, the power converter, and the plurality of the memories are mounted on a first surface of the package substrate,
wherein the power converter is in the center of the first surface,
wherein the plurality of the processors are arranged so as to surround the power converter,
wherein the plurality of the memories are arranged in a first direction with the plurality of the processors and the power converter interposed between the plurality of the memories, the first direction being parallel to the first surface, and
wherein the plurality of the photoelectric converters are arranged in a second direction with the plurality of the processors and the power converter interposed between the plurality of the photoelectric converters, the second direction being parallel to the first surface and being orthogonal to the first direction.

16. The electronic circuit module according to claim 1, further comprising:
memory that is connected to the processor,
wherein the photoelectric converter, the processor, and the memory are mounted on a first surface of the package substrate,
wherein the power converter is mounted on a second surface of the package substrate, and
wherein, when viewed in a direction orthogonal to the first surface and the second surface, the power converter at least partially overlaps the photoelectric converter, the processor, and the memory.

17. The electronic circuit module according to claim 1, further comprising:
memory that is connected to the processor;
a plurality of the power converters; and
a plurality of the photoelectric converters,
wherein the plurality of the photoelectric converters, the processor, and the plurality of the power converters are mounted on a first surface of the package substrate,
wherein the processor is in the center of the first surface,
wherein the plurality of the photoelectric converters are arranged so as to surround the processor,
wherein the plurality of the power converters are arranged in outer corners formed by arrangement of the plurality of the photoelectric converters, and
wherein, when viewed in a direction orthogonal to the first surface, the memory overlaps the processor, and is arranged opposite the package substrate, with the processor interposed in between.
